(19) United States
(12) Patent Application Publication
(10) Pub. No.: US 2011/0308566 A1
(43) Pub. Date: Dec. 22, 2011

(54) PHOTOVOLTAIC MODULE AND THE WAY OF CONNECTING PHOTOVOLTAIC MODULES IN A PHOTOVOLTAIC SYSTEM

(75) Inventor: Peter Herbert Johnson, Fialkinge (SE)

(73) Assignee: Alien Inspired Technologies AIT SP. Z O. O., Tarnow (PL)

(21) Appl. No.: 13/148,726

(22) PCT Filed: Feb. 22, 2010
(86) PCT No.: PCT/PL10/00017

§ 371 Date: Aug. 10, 2011

(30) Foreign Application Priority Data
Feb. 28, 2009 (PL) P-387368

(51) Int. Cl. H01L 31/05; H01L 31/18; H01R 43/20

(52) U.S. Cl. 136/244; 29/876

(57) ABSTRACT

The present disclosure relates to a solution enabling to lead out from the front of the photovoltaic module poles (+, −) of the electric wiring of the module's circuit by the use of glass applied in photovoltaics, with holes going through (1, 12) through the front (4) and the rear (3), as well as proper connectors (plugs) (8, 13) which enable to mount the wiring (15). Owing to that, it is possible to introduce a facilitated way of connecting modules by using short wires without connectors, which diminishes the losses of power caused by the earlier solution.

The object of the invention is a photovoltaic module which allows to convert solar energy into electric energy and at the same time enables easy mounting on various surfaces, and the way of connecting these modules in a photovoltaic system of any power.

The basic electron device used to convert solar energy into electric energy by means of the photovoltaic effect is called a photovoltaic or solar cell. It is formed in a semiconductor material in which, under the influence of radiation absorption, a voltage forms on the terminals of the device. After adding a load to the terminals, electric current passes through them. The most common material used in the production of the cells is silicon. A typical photovoltaic cell is a semiconductor wafer made of crystalline or semi-crystalline silicon in which the barrier of potential has been formed, for example in the form of a p-n junction. The thickness of the wafers is between 200-400 micrometers. On the front and rear side of the wafer metallic junctions are applied, being contacts and letting the wafer act as a photovoltaic cell. The cells of mono-crystalline silicon are made of wafers of round shape, and then they are cut into squares to increase packing on the surface of the module. Mono-crystalline photovoltaic cells show the biggest conversion efficiencies of all silicon cells but they are also the most expensive to produce. In the laboratory research, single cells reach efficiencies of 24%. The cells produced on mass scale have efficiencies of about 17%. Poly-crystalline silicone cells are made of large cubicoid blocks of silicon produced in special furnaces which slowly cool the melted silicon to initiate the increase in the large grain poly-crystal. These blocks are cut into rectangular wafers in which the barrier of potential is also formed. Poly-crystalline cells are a little less efficient than mono-crystalline ones but their production costs are also a bit lower. At present, photovoltaic industry is based mainly on crystalline and poly-crystalline silicon (in 1997—about 80% of the global production). The basic advantages of this technology are: the possibility to use experience of highly-developed semi-conductor industry (micro-electronics), relatively high efficiencies of converting solar radiation, the simplicity and very good stability of work. However, such cells are relatively thick and, using a lot of expensive material, they have a limited size and have to be connected, thus the modules are not monolithically integrated. Cells of amorphous silicon are commonly used in products which require low supply power (pocket calculators, watches, etc). The advantages of the cells produced of amorphous silicon are: low costs of the material, small consumption of energy in the production of the module (mainly due to low temperature of the process), the possibility to place on flexible substrates, integrated junction of cells and the possibility to obtain large surfaces. The cells and the modules may be produced in any shapes and sizes and may be designed in the way which enables the integration with facades and the roofs of buildings or in the form of roof tiles. They may be designed as transparent or semi-transparent ones. However, the efficiency of the cell is lower than in case of crystallite silicon. The photovoltaic cell is a basic element of the photovoltaic system. A single cell usually generates between 2-4 W, which is insufficient for the majority of applications. To obtain bigger voltages or currents, the cells are connected serially or in parallel, forming a photovoltaic module. The modules are encapsulated in order to protect them against corrosion, moisture, impurities and the influence of atmosphere. The casings must be durable since the expected lifetimes for photovoltaic modules are at least 20-30 years.

Photovoltaic systems consist of numerous photovoltaic modules which have been interconnected to obtain bigger powers. They generate direct current. The current level on the panel output depends strictly on insolation but it may be increased by the parallel connection of the modules. The voltage obtained from the module depends to a small extent on the level of insolation. Photovoltaic systems may be designed for work with practically any voltage up to a few hundred volts, owing to the serial connection of modules. For small applications, photovoltaic panels can work only at the voltage of 12 or 24 volts whereas for the applications connected to the grid, big panels can work at the voltage of 240 volts or more. Photovoltaic modules are built of interconnected photovoltaic cells which convert solar energy into electric energy. The cells are between the glass and the adequate laminating foils protecting cells against mechanical, physical and chemical factors which influence the degradation of the cells. The whole electric circuit of the cells connected in the module is led out outside the module by means of proper sockets at the rear of the module, where appropriate wiring is mounted. This wiring serves to connect the modules in photovoltaic systems. This way of mounting sockets with wires at the rear of the modules makes the access more difficult during mounting and connecting modules in building integrated systems and modules installed on roofs.

From the condition of technique, photovoltaic modules are known in which the wiring of each module is mounted permanently inside the photovoltaic module, and the wires are led outside at the rear of the module through the casing. By means of connectors, the wiring of particular modules is connected into photovoltaic systems.

The object of the invention is a photovoltaic module built of silicon wafers interconnected in the electric circuit, applied on the sheet of photovoltaic glass mounted in the casing in such a way that in the photovoltaic glass constituting the front of the module there are holes in which connectors are built-in, having the structure which enables the wiring to be installed outside the module.

The connectors are in the shape of cylinders perfectly fitted to the hole sizes. The inside of the connectors is shaped in such a way that together with the terminal of the wiring they form permanent and easy connection, owing to which it is possible to connect modules in the photovoltaic systems of unlimited power.
The connectors are directly connected to the electric circuit of the module and are made of the material which conducts electric current, as well as of insulating caps which serve to protect the connector against the contact with the external environment.

The way of connecting photovoltaic modules in a photovoltaic system according to the invention consists in connecting photovoltaic modules in systems by means of wiring without the connectors' help, and specially designed connections enable to mount wiring from two sides directly to the connectors in the photovoltaic modules, while this junction is constituted by the casing of the wiring terminal with the cover, taken off during the wiring mounting, which, on closing, tightly blocks against the air getting into electric elements and protects the elements against the contact with the external environment.

The wire is protected with by the choke of the casing. At the end of the wire on both sides there are caps connected to the wires. Through the caps there passes an element which serves to fasten wires directly to the connector in the photovoltaic module. The element is of a shape which enables to make an easy and permanent connection which lets conduct electric current.

The invention described enables to lead out the wiring form the front of the module thanks to appropriate holes in the glass being the front element of the photovoltaic module and the properly fitted connectors (plugs) and the proper isolation. The wiring, specially designed for this purpose, can be directly assembled to the connectors. Thanks to this solution, it is not necessary to install sockets with wires at the rear side of the module. The access to the wiring at the front of the module makes the way of mounting it easier. The new solution enables to connect and install the modules very close to each other, and at the same time it to increase the efficiency of the whole installation. The lack of connectors and the small length of the wires significantly decreases the losses related to the resistance of the junction's transition.

The invention has been presented in the example of the execution which aims at displaying its application. However, one must realize that the described example does not show all possible applications of the solution.

The holes 1, made in glass 2 used in photovoltaics, are designed to lead out and to enable the connection of wiring 15 at the front of the photovoltaic module 4. The holes 1 are produced by the photovoltaic glass producer. The glass fulfils the requirements for this material used in the photovoltaic industry. The holes I have a proper shape fitted to the shape of the connectors 8, 13 mounted in the photovoltaic module 20.

What also decides about the novelty of this solution are connectors (plugs) 8, 13, made of a material well conducting current (copper covered with tin). The connectors 8, 13 have a flange 7 which is placed under the glass 2, constituting an additional strengthening of the whole junction. The flanges are soldered directly to a ribbon made of the material conducting current, connecting single photovoltaic cells into a module, which ensures leading out and conducting current on two different poles of the electric circuit (plus and minus). The height of the walls of the connector 8 and 13 is adapted to the depth of the hole in the glass 1 and the hole 6, 10 situated inside the connector 8, 13, to which the wiring 15 of the photovoltaic module is installed. The connectors 8, 13 are mounted in the holes in the photovoltaic glass in module 20 before the lamination process.

On the connector 8, 13 an isolation seal 5, 11 is applied, made of a material which does not conduct current, characterized with high resistance to the factors related to later stage of production, namely the lamination—high temperature.
The isolation seals are to protect the connectors 8, 13 conducting current against the contact with the external environment and against the atmospheric conditions. They also cushion the junction of the connector walls and the edges of the hole in the glass. This tight adhesion of the connector with the isolation seal to the edge of the hole 1 in the glass protects against flowing out of the lamination foil (EVA) from the inside of the module during the lamination process.

What also decides about the novelty of the solution is also the way of connecting the modules in the photovoltaic systems. The kind of the applied wiring 15, which does not possess connectors, and specially designed junctions enable to mount from two sides the wiring directly to the connectors 8, 13 in the module 20. This junction is constituted by the casing 16 with the cover 17, taken off during mounting, which, on closing, tightly blocks the junction against the air getting in to the electric elements, and protects the elements against the contact with the external environment. The wire 15 is protected with the choke of the casing 16. At the end of the wire on two sides there are caps 19 soldered to the wires 15. The element 18 goes through the caps, which serves to fasten the wires directly to the connectors 8, 1, in the module 20. The shape of the element 18 and the shaping of the inside of the connectors 8, 13 allow to execute the permanent junction by contortion or the junction of the “jack” type, or another separable junction used to connect the elements conducing current.

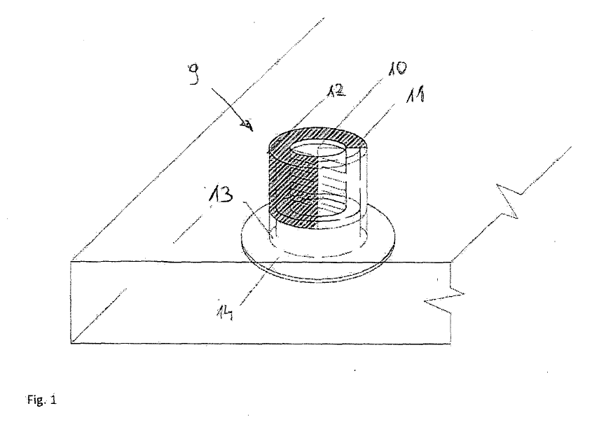

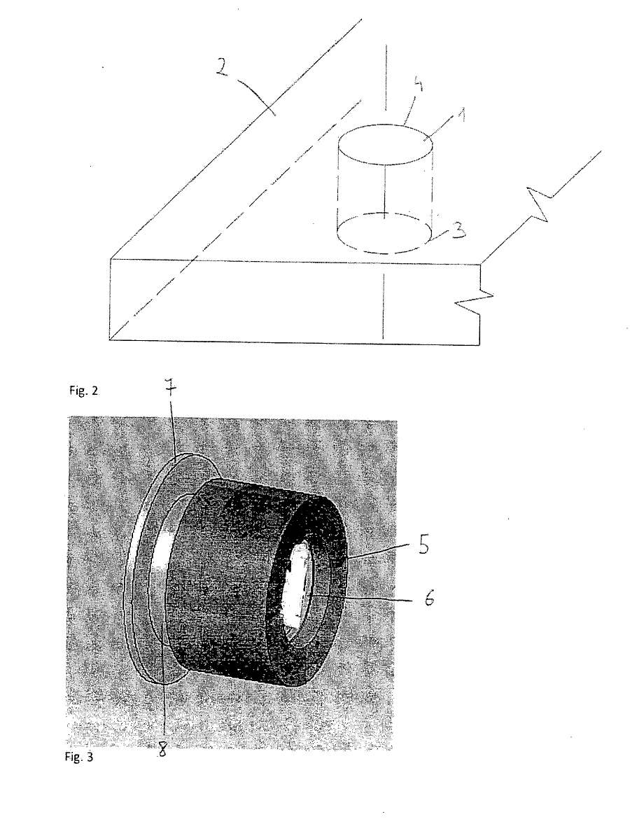

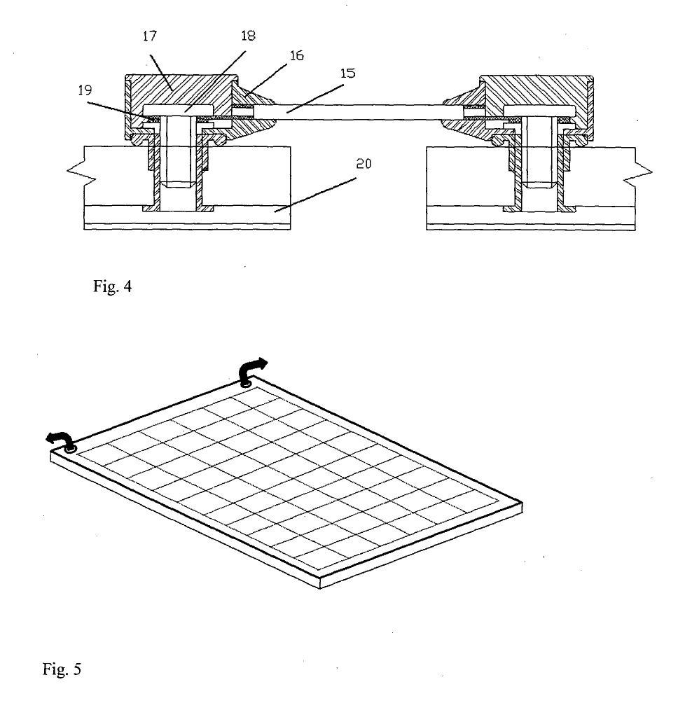

The object of the invention has been presented on the examples of the execution in the drawings where FIG. 1 shows a hole in the glass with the mounted connector together with the isolating seal, FIG. 2 shows holes in the glass constituting the front of the module, which enables to lead out the electric circuit outside the module in its front part, FIG. 3 shows the connectors together with the isolating seal, mounted in the glass, enabling to mount the wiring directly to the module, FIG. 4 shows a new solution for the junctions between two modules and the way of mounting them, and FIG. 5 shows a general idea of the invention.

The invention may be described with a limitless number of examples. The presented figures do not restrict the possibilities of using the invention, they present one of the ways of mounting the wiring.

The invention enables to connect the photovoltaic modules in a photovoltaic system by means of the wiring with special construction without the use of connectors with a possibility to mount the wiring directly to the plugs—the connectors, and the obtained junction is protected against the influence of external factors and makes it impossible for the electric elements to contact the external environment.

The way according to this invention allows to build photovoltaic systems on any surface easily and without any special restrictions. It also enables an easy access to the elements of the wiring.

1. The photovoltaic module built of silicon wafers which are interconnected in the electric circuit, applied on the wafer of the photovoltaic glass fitted in the casing, wherein in the photovoltaic glass constituting the front of the module there are holes, in which connectors are built-in, with appropriate structure which enables the mounting of the wiring outside the module.

2. The photovoltaic module, in accordance with claim 1, wherein the connectors are in the shape of cylinders perfectly fit to the sizes of the holes, and their inside is shaped in a way which enables to connect modules in photovoltaic systems of any power easily and permanently.

3. The photovoltaic module according to claim 1, wherein the connectors are directly connected to the module's electric circuit.

4. The photovoltaic module according to claim 1, wherein the connectors are made of a material which conducts electric current and the isolating caps which serve to protect the connector against the contact with the external environment.

5. The way of connecting photovoltaic modules in the photovoltaic system, wherein the photovoltaic modules are connected in systems by means of wiring, without the use of connectors, and specially designed junctions enable from two sides to mount the wiring directly to the connectors in the module, while the junction is formed by the casing with the cover taken off during the mounting of the wiring, which, on closing, tightly blocks against the air coming in to the electric elements and protects the elements against the contact with the external environment.

6. The way of connecting the photovoltaic modules in a photovoltaic system according to claim 5, wherein the wire is protected with the choke of the casing, at the end of the wire on two sides there are caps connected to the wires, through the caps there goes an element which serves to fasten the wires directly to the connector in the module shaped in such a way that it enables to obtain a permanent connection facilitating the flow of electric current.
